(19) United States
(12) Patent Application Publication
(10) Pub. No.: US 2014/0091783 A1
(43) Pub. Date: Apr. 3, 2014

(54) SYSTEM AND METHOD FOR MONITORING AC RIPPLE

(71) Applicant: Canara, Inc., San Rafael, CA (US)

(72) Inventors: Stephen D. Cotton, San Rafael, CA (US); John M. Brinck, San Rafael, CA (US); Ronnie Lim, Elk Grove, CA (US); Jason W. Toomey, Fairfax, CA (US); Bradley W. Lockhart, South Boardman, MI (US)

(73) Assignee: Canara, Inc., San Rafael, CA (US)

(21) Appl. No.: 14/038,510

(22) Filed: Sep. 26, 2013

Related U.S. Application Data
(60) Provisional application No. 61/705,859, filed on Sep. 26, 2012.

(51) Int. Cl. G01R 23/02

(52) U.S. Cl. CPC G01R 23/02
USPC 324/76.39

(57) ABSTRACT

A system capable of identifying various possible technical malfunctions with an uninterruptible power supply system by detecting AC ripple on a power bus of the UPS system. A battery monitor is positioned on the terminal posts of one or more batteries of the UPS system. The monitor, since it is connected with the power bus, is configured to measure and/or record AC ripple on the power bus. At the monitor or by way of communicating the AC ripple to a remote database and server, excessive ripple changes may generate an alert when such changes exceed a threshold or may be viewed through a graphical user interface.

### CROSS REFERENCE TO RELATED APPLICATION

The present application is a nonprovisional utility application claiming priority under 35 U.S.C. §119 to co-pending provisional application No. 61/705,859, titled “SYSTEM AND METHOD FOR MONITORING AC RIPPLE,” filed on Sep. 26, 2012, the disclosure of which is hereby incorporated by reference.

### TECHNICAL FIELD

Aspects of the present disclosure relate generally to monitoring AC ripple, and more particularly to monitoring AC ripple from a UPS system and identifying UPS malfunctions, failures, out of tolerance components, and other problems based upon the AC ripple signal.

### BACKGROUND

Uninterruptable power supply (UPS) systems are critical to maintaining proper operation of a data center and all of the computing equipment within such data centers. During a power failure, the UPS system activates and temporarily supplies power to the data center until normal power returns. Thus, it is important to maintain and identify problems with UPS system components so such components are available in the event of a power failure and do not themselves fail when called upon during such power failures.

It is with respect to these and other considerations that embodiments of the present disclosure have been made.

### SUMMARY

Aspects of the present disclosure involve a system, method and apparatus whereby various UPS system component malfunctions, problems, or complete failures may be identified. In one particular example, ripple current and/or ripple voltage is monitored. Increases, decreases, and other changes associated with the ripple may indicate problems, depending on the change in the ripple, with various UPS system components including connections, rectifier electronics, inverter electronics, UPS battery monitors, batteries themselves, as well as the various components connected the UPS system.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Other features, details, utilities, and advantages of the present disclosure will be apparent from the following more particular written description of various embodiment of the disclosure as further illustrated in the accompanying drawings and defined in the appended claims.

### BRIEF DESCRIPTION OF THE DRAWINGS

FIG. 1 a system diagram of a UPS system and monitoring system configured to measure and record battery parameters as well as AC ripple waveforms that may indicate problems with UPS system components, batteries, battery monitors, monitoring infrastructure, among other problems;

FIG. 2 is a diagram depicting (1) an AC voltage waveform from a rectifier transformer secondary output, (2) a rectified AC voltage waveform. and a (3) rectified voltage form after processing by one or more capacitors that smooth the rectified signal but typically leave some nominal amount of AC ripple;

FIG. 3 is a diagram illustrating an initially nominal ripple voltage on a DC power bus of a UPS system, with the peak-to-peak ripple voltage increasing in two distinct areas on an elevating nominal DC power bus current indicating the malfunction of UPS rectifier components;

FIG. 4 is a diagram illustrating an initially nominal ripple voltage on a DC power bus of a UPS system, followed by anomalous peak-to-peak ripple voltage fluctuations increasing and upwardly trending over time indicating improper operation of SCR components.

FIG. 5 is a diagram illustrating a relative large stepwise increase in ripple with an accompanying DC power bus carrier current increase from about 1 amp (nominal) to about 8 amps (nominal).

FIG. 6 is a diagram illustrating a relative large stepwise increase in ripple, about double nominal ripple, with an accompanying DC power bus carrier current increase from about 1 amp (nominal) to about 12 amps (nominal).

FIG. 7 is a series of related measurements showing (A) a decrease in ripple voltage, (B) an associated decrease in the voltage of a particular battery, and (C) an associate increase in impedance for the particular, collectively and individually identifying an failure of a particular battery (or cell within a battery).

### DETAILED DESCRIPTION

Aspects of the present disclosure involve apparatus, systems, and methods for monitoring nominal and anomalous alternating current (AC) ripple on a UPS direct current (DC) power bus and thereby determine when there may be problems with various aspects of a UPS system. Generally speaking, a UPS system in accordance with aspects of this disclosure includes some form of electronics that converts conventional AC power into DC power and supplies the DC power to a DC power bus, a battery array that provides DC power to the bus in the event of a power failure, an inverter that converts the DC power back to AC power, and battery monitoring components that are connected to individual batteries that are configured to measure various possible battery parameters. The battery monitoring components are also configured to detect AC ripple on the DC power bus as well as AC ripple at the battery, which may or may not be the same as the AC ripple on the bus. The AC ripple measurement may be compared with a threshold in order to identify anomalous behavior. Such comparison may further be used to trigger an alarm, set a flag, or provide some other indication of a possible UPS system problem. Further, this information may be detected locally at the monitor but may also be transmitted to some form of remote monitoring computer for further analysis, either alone or in conjunction with other battery measurements, whether discrete or across a string or collection of batteries.

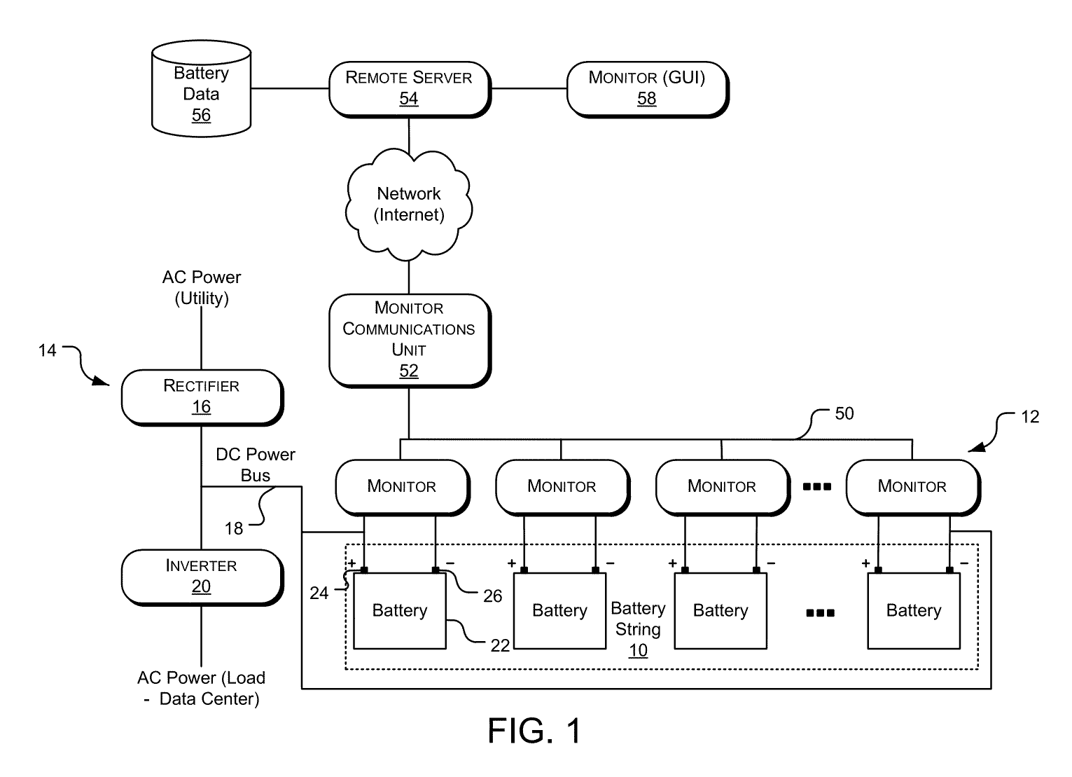

FIG. 1 is a diagram illustrating an uninterruptible power supply (UPS) battery string 10 and AC ripple monitoring system 12 in accordance with aspects of the present disclosure. In a UPS system 14, alternating current (AC) power is supplied to a rectifier 16 that converts the AC power (voltage) to direct current (DC) power (voltage). The DC voltage is coupled to a power bus 18 that in turn is connected with one or more strings of batteries 10. While the UPS system is idle, the DC power bus provides a charge current to the batteries. Thus, there is typically a nominal voltage or current level present on the power bus while the batteries are being maintained but are not providing back-up power as during a power failure. Further, there is typically a nominal and normal AC ripple superimposed on the power bus. The DC bus is also coupled with an inverter 20 that converts DC power to AC power for distribution to a load, such as to various components in a data center. When power from the utility is lost, due to a lightning strike or other interruption, power supplied to the load switches immediately from the AC power to the battery string 10. Thus, the battery string supplies power to the bus 18 thereby keeping the data center's components operational for a limited period of time until a generator comes on-line and replaces the power supplied by the batteries.

In the system illustrated a series of battery monitors 12 are coupled to the respective batteries. A given battery 22 may include a positive 24 and a negative post 26 and is accompanied by a voltage potential measureable across the posts. For example, many data centers include UPS systems with conventional lead acid batteries that provide approximately 12 Volts DC. A string of such 12 volt batteries are connected in series to form a string 10 that provides the appropriate DC voltage for the DC bus 18. So, for example, 10 batteries connected in a series string provide approximately 120 VDC to the DC power bus. Further, several strings may be connected in parallel to ensure that the batteries can supply the appropriate current and power to the DC bus for some specified amount of time.

The battery monitors 12 are connected to the respective batteries, such as through Kelvin connections, to measure various parameters, such as inductance and temperature, of each battery in a string. The battery monitor is configured to inject a small AC current, at various possible frequencies, into the battery and thereby measure inductance. In the present application, the battery monitors are also configured to monitor the AC ripple current present on the DC power bus, which may be detected at the battery posts by the monitor. In one example, the ripple voltage is recorded when the injection current is used to measure inductance. In some instances, the injection current is also modified so that its peak-to-peak value and/or frequency is sufficiently different from the AC ripple as to clearly identify ripple and/or clearly obtain an accurate inductance measurement. As will be discussed in greater detail below, the AC ripple current can provide various indications of problems present in the UPS system, such as problems in the rectifier 16 or inverter 20. These problems, if left uncorrected, can lead to a failure of the UPS system 14 during a power failure. Further, while some amount of AC ripple on the DC power bus is normal, fluctuations, excessive ripple, or other abnormalities in the AC ripple present on the power bus 18 can also damage batteries, reducing life, capacity, or causing failures. AC ripple may be measured at any one or combination of the battery monitors 12 coupled with the various batteries.

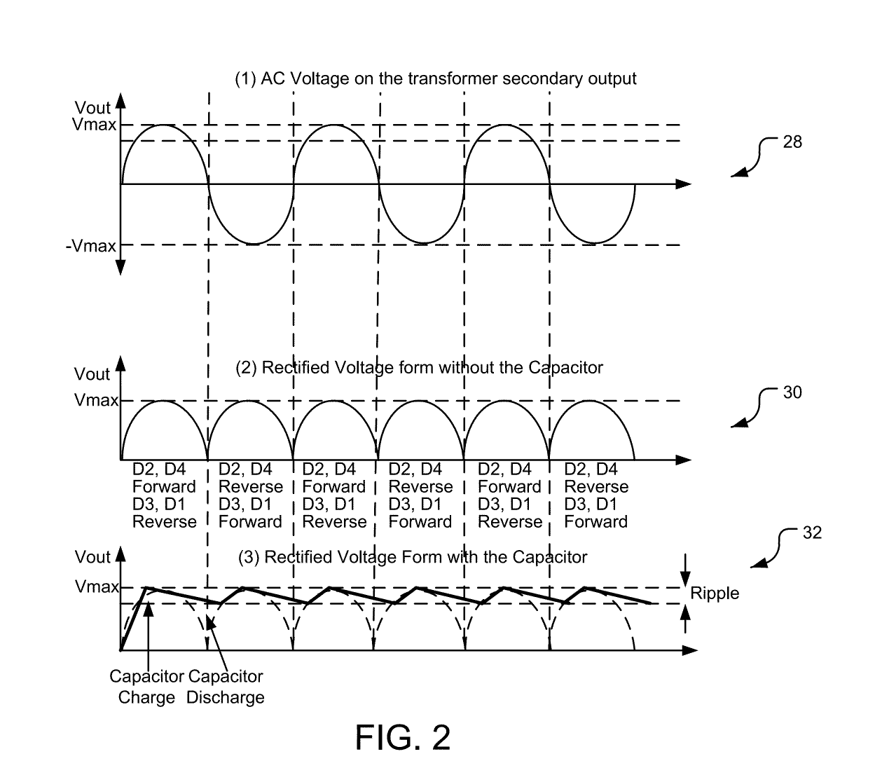

One form of conventional rectifier used in UPS system involves one or more silicon controlled rectifiers (SCRs), the various control electronics for the SCR, capacitors and filters. These components, when operating properly, maintain the AC ripple below some specified level. When the rectifier or some combination of its constituent components malfunction, fail or begin operating out of tolerance, AC ripple may be effected and may be used to identify and diagnose such problems. FIG. 2 illustrates a conventional AC waveform 28 received at the rectifier 16, the rectified waveform 30, and the rectified voltage waveform when smoothed by a bank of capacitors 32. As illustrated, some amount of ripple 34 is normally present after rectification and capacitor filtering. Besides the rectifier components, problems with other UPS components, such as the inverter, the batteries themselves, the battery monitors, connections, and the like may exhibit themselves by changes from the nominal AC ripple 34.

Excessive ripple voltage and current are traces of improperly filtered remnants from the output of the AC to DC rectification process. In cases were DC capacitors and rectifier components are not functioning properly, adequate filtering cannot be achieved either due to performance decreases or failures of the capacitors and/or un-uniform rectifier peak waveforms caused by phase imbalances or degradation. The UPS rectifier is a finely tuned circuit and having any number of these misaligned can cause the UPS inverter to fail leading to expensive downtime.

Traditional battery monitors lack the option of monitoring AC ripple voltage and current, since by design such conventional monitors are only meant to measure battery performance. Further, conventional UPS systems themselves lack the ability to discern a high ripple voltage or current condition and therefore such problems often go undetected until there is a failure, such as the DC capacitors rupturing, SCR board failures, inverter failures, or other failures.

The monitor described herein is a sophisticated testing device that can measure discrete values such as voltage, impedance and battery temperature, as well as AC ripple voltage and current. Thus, systems conforming to the present disclosure now have the capability to monitor the AC ripple in addition of having the ability to weed out weak or failing batteries through a statistical, prognostics and trend analysis approach, avoiding the consequences of a UPS load loss.

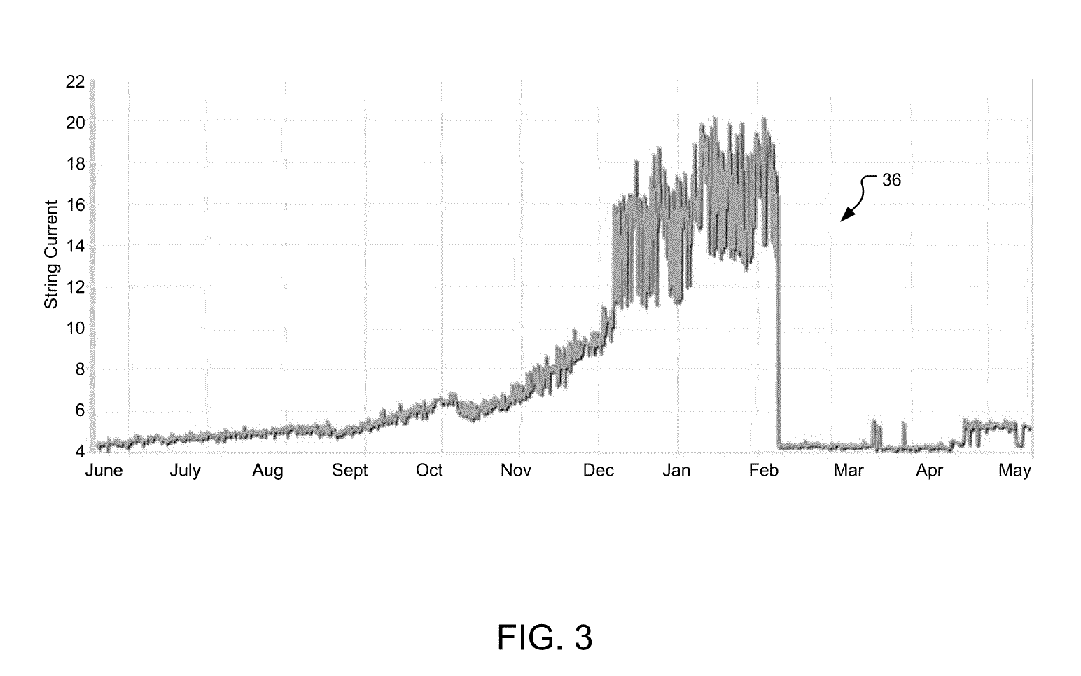

Turning now to FIG. 3, an AC ripple signal 36 on a DC bus 18 is shown. The graph represents AC ripple current noticeably trending higher over a period of time. In this example, the AC ripple current ripple (the difference between the high and low current measurement of the ripple) doubled in one month and then quadrupled within as little as three months. Additionally, the output current carrying the ripple, also trended higher over this period with the slope increasing when the ripple doubled, and the slope increasing again when the ripple quadrupled. In this example, the drive boards for an SCR rectifier were replaced, at which time the ripple and base current dropped significantly and stabilized. Thus, the AC ripple increase reflected a problem with the SCR driver boards. Left uncorrected, high AC ripple current will eventually lead to excessive battery gassing, battery dry out and a shortened life expectancy requiring premature replacement of the batteries. Also, the SCR boards may fail completely, resulting in a disabled UPS system.

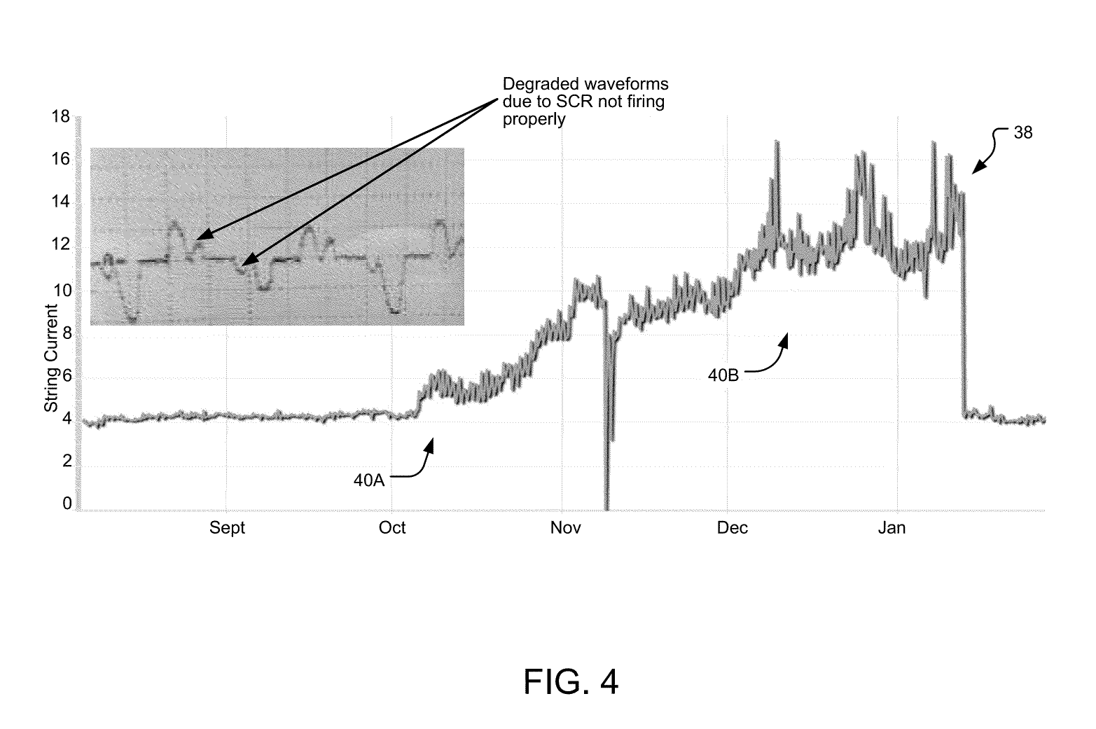

Similarly, FIG. 4 also illustrates how a battery monitor configured to detect, record, and transmit information indicative of AC ripple, was used to detect a malfunctioning SCR component. More particularly, the graph depicts the service history of a UPS system with high ripple current 38 where the monitoring system detected a relatively significant ripple change on a first date 40A that escalated at a later date 40B. In this case, the ripple change and fluctuations reflected a catastrophic DC capacitor failure in the form of a rupture. The rupture, however, did not cause any alarm in the UPS system. The failure was thus only detected by the battery monitoring system ripple voltage functionality. The DC capacitors were replaced and the UPS system was placed back into service but upon re-measuring the AC ripple voltage and current, the measurements remained out of tolerance, indicating that other potential problems still existed within the UPS. Upon further inspection, a malfunctioning SCR driver board was discovered that was degrading the rectifier waveform on the DC bus. The bad board caused un-uniform peak waveforms prone to improper filtering, and may have also have contributed to the failure of the capacitors.

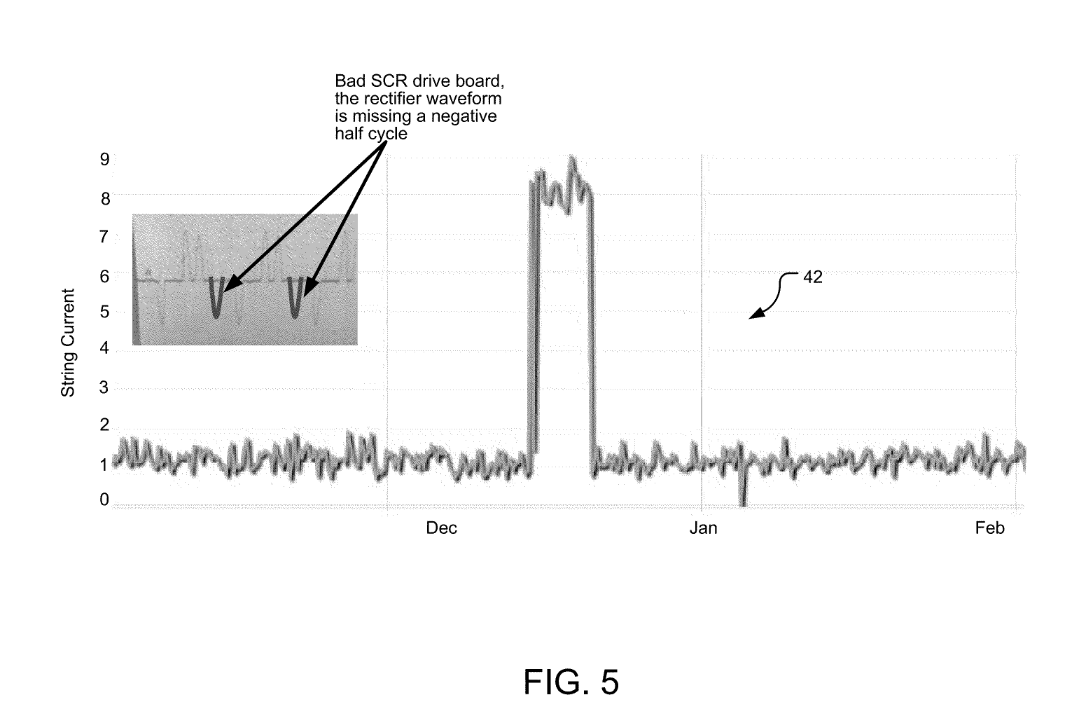

FIG. 5 illustrates a graph that displays an elevated AC ripple current measurement 42 indicative of a failing rectifier drive board. Although the drive board was not properly gating it did not display any alarms on the UPS. Once the high ripple current condition was identified, a UPS service technician was dispatched. An oscilloscope meter screen shot was taken illustrating that the driver board was gating only 50% of the time on the negative cycle. The rectifier in a UPS is a tuned circuit so any imbalance will manifest itself with excessive ripple values. An oscilloscope meter screen shot was taken illustrating deteriorated drive signals (40% the required amplitude). After the SCRs were replaced, the ripple returned to a value within tolerances and therefore substantiated that the corrective maintenance was successful.

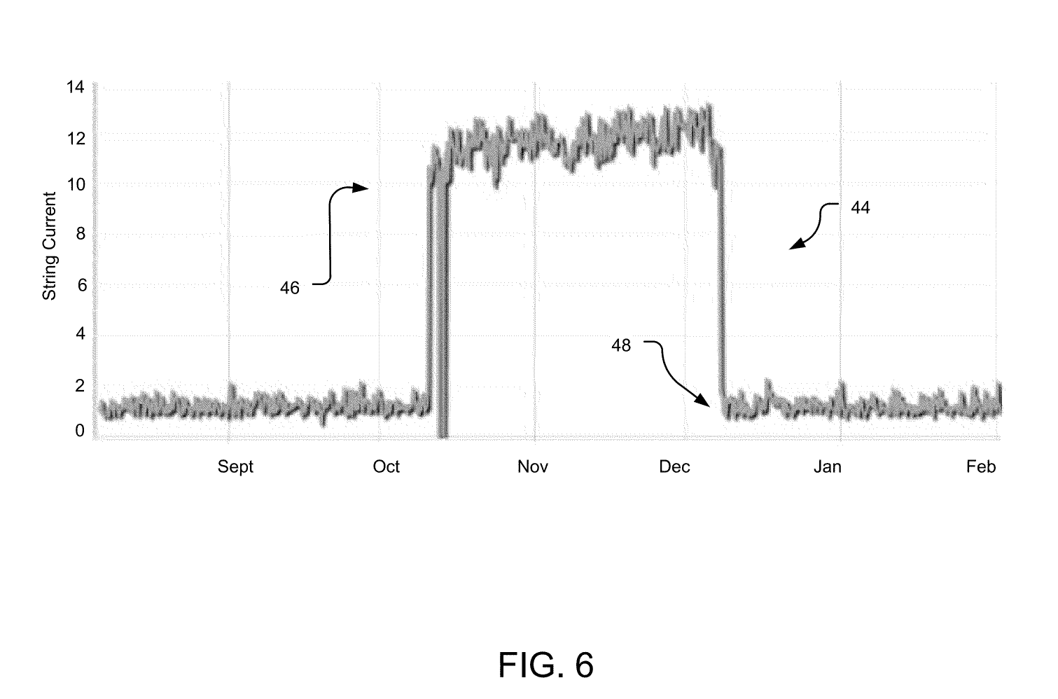

FIG. 6 is a graph that displays an elevated AC ripple current measurement indicative of a failing or aging DC capacitor or capacitors 44. Here, the baseline current is elevated and the ripple has increased at a first point 46. When the DC capacitors were replaced, the baseline current and ripple returned to a value 48 similar the event prior to the DC capacitors failing.

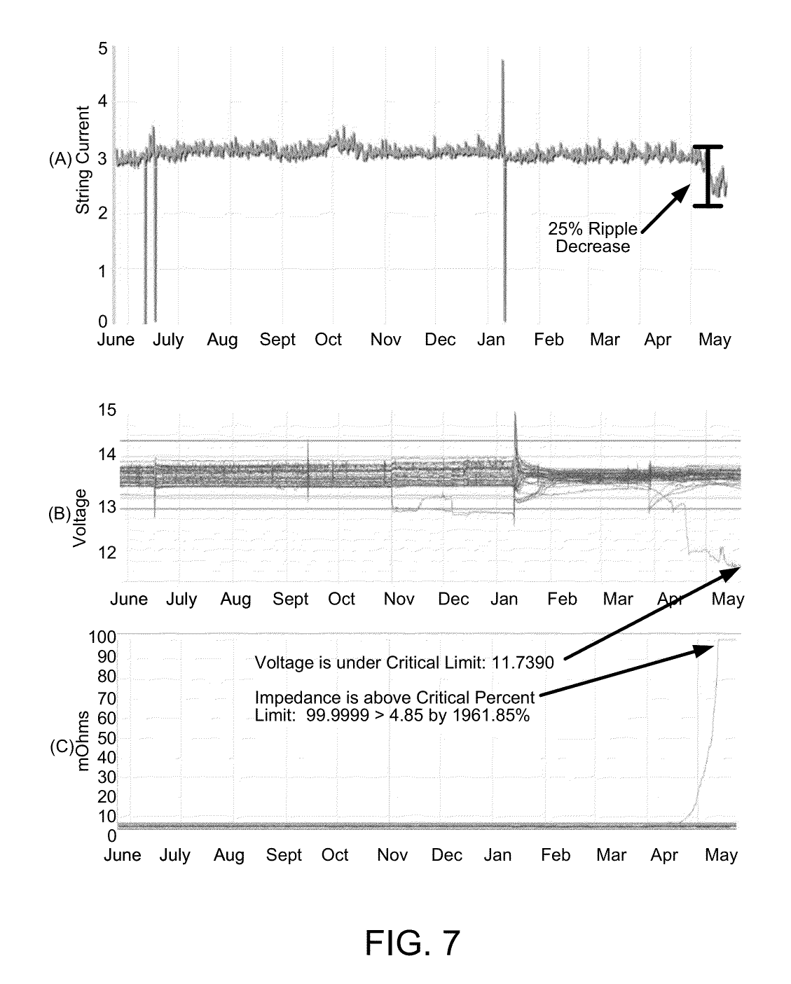

Excessive ripple current may also be indicative of a battery problem. FIG. 7A is a graph illustrating a decrease of AC ripple current. Unlike previously discussed graphs that show increases in ripple current, here, excessively low AC ripple current values pinpoint problems associated with bad batteries becoming resistive (open condition) and essentially rendering the battery string useless during an AC utility outage event. So, while an increase in ripple current prompts diagnostic actions related to rectifier or inverter components, a decrease in ripple current may prompt diagnostic actions related to batteries.

To complement and confirm the ripple measurements of FIG. 7A, FIG. 7B and 7C, illustrate the suspect battery's voltage and impedance that correlate to the low ripple current condition of the battery string. Note that the ripple change corresponds to the aggressive impedance rise (7C) and voltage drop (7B) of the bad battery over a 15 day period. Thus, the ripple drop corresponds with conventional impedance and voltage measurements indicative and used to detect battery problems.

Returning to FIG. 1, in one possible implementation, the various individual battery monitors 12 collect battery data and AC ripple data (current and/or voltage). This data may be temporarily stored locally. The data is communicated over a data bus 50 to a monitor communication unit 52. The bus and communication over the bus may conform to the controller area network (CAN) protocol. The monitor communication unit is configured to share data with a remote server 54 and to provide the data to a database 56 in communication with the remote server. In one example, the remote server (or servers) may implement a BAR system. Aspects of the BAR system, database, battery monitors, etc., are disclosed and discussed in U.S. Pat. Nos. 7,768,238; 7,576, 517; and 7,474,228; the disclosures of which are hereby incorporated by reference herein.

In one implementation, the AC ripple measurements are transmitted to and stored in the database, and the various graphical representations illustrated herein are accessible and manipulable by way of a monitor 58 providing a user with access to a graphical user interface. In one possible implementation, the battery monitoring unit collects the ripple data and it is stored in the database, where it associated with a particular battery, string of batteries, DC power bus, and or UPS unit. At a fundamental level, the AC ripple display in conjunction with other monitored aspects, may be displayed so that a user can determine when and what action may implemented.

The server, the battery monitors, and/or the battery monitor communication unit, may be configured to automatically compare the ripple waveform with various possible thresholds. So, for example, a base AC ripple with a peak-to-peak voltage of X may be configured to be within a normal operating tolerance. Various possible thresholds may then be configured to automatically trigger alarms at the remote server or locally at the battery monitors, battery monitor communication unit, or otherwise. For example, thresholds of X+X′ and X−X′ may trigger a first alarm indicative of possible problem, and thresholds of X+X″ and X−X″, where X″ is greater than X′, may trigger a second alarm indicative of more serious problem. In one specific instance, the battery monitor maintains a threshold, and when an AC ripple measure exceeds the threshold it is flagged within the locally stored measurement. When the flagged ripple measurement is received at the battery monitor communication unit, the unit maintains the flag when it transmits the data to the remote database. It may also expedite the data transfer and the remote server may cause some form of alarm within the BAR system.

Additionally, the system may be configured to monitor the base DC float current or voltage of the DC bus upon which the AC ripple is superimposed. In such situations, the system may compare the float value to a threshold and trigger various possible responses when the float value exceeds a threshold. The float value may also be compare to a slope and should the float slope increase or decrease outside of a threshold, then an alarm may be triggered. It is also possible, to combine peak-to-peak ripple measurements with float value measurements, and compare against thresholds. Depending on the implementation, the threshold comparisons may trigger graphical indications, such as yellow or red, lines, when thresholds are exceeded. Such indications providing a user with a visual prompt as to a possible concern with a UPS system or component or a battery problem. Additionally, threshold values may also be graphically illustrated so that a user can visualize when and to what extent a measurement exceeded a parameter.

In another alternative, various verified failure events, such as some of those illustrated in the various figures herein, may be saved. When new ripple measurements are received at the remote server and database or at other components of the system, the new ripple measurements may be compared to the saved ripple measurements, and when there is a match an alarm or some other form of notification of possible problem may be indicated. Further, the type of problem, or ranking of types of problems if there are multiple matches, may further be included as part of the notification.

Various possible computing devices or systems, including some form of memory, may be used to implement the remote server used to manage the database, BAR system, and component that generate the various graphical representations set out herein. A particular battery monitor may also include a processor, and other components, including Kelvin connectors as well as the circuitry necessary to monitor ripple as well as other battery parameters. Embodiments of the present disclosure may include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware. A machine-readable media may take the form of, but is not limited to, non-volatile media and volatile media. Non-volatile media may include a mass storage device and volatile media may include dynamic storage devices. Common forms of machine-readable medium may include, but is not limited to, magnetic storage medium (e.g. floppy diskette); optical storage medium (e.g. CD-ROM), magneto-optical storage medium; read only memory (ROM); random access memory (RAM); erasable programmable memory (e.g., EPROM and EEPROM); flash memory; or other types of medium suitable for storing computer instructions.

While the present disclosure has been described with reference to various embodiments, it will be understood that these embodiments are illustrative and that the scope of the disclosure is not limited to them. Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternative, modifications, and variations together with all equivalents thereof.

1. An apparatus for identifying a problem with an uninterruptible power supply (UPS) system comprising:
at least one battery monitor coupled with at least one of a plurality of batteries forming part of a UPS system, the at least one battery monitor configured to record AC ripple measurements present on a DC power bus of the UPS system, the DC power bus coupled with the plurality of batteries.

2. The apparatus of claim 1 wherein the battery monitor is configured to measure a battery parameter by applying a current load to the battery that the monitor is coupled with, the battery monitor further configured to measure and record the AC ripple when the current load is applied to the battery.

3. The apparatus of claim 1 wherein the battery monitor further includes at least one network connection, the battery monitor configured to transmit the recorded AC ripple measurements to a remote database over the network connection.

4. The apparatus of claim 3 wherein the battery monitor further includes a local memory storing at least one threshold, the battery monitor comparing the monitored AC ripple measurement with the threshold and generating an indicator when the threshold is met.

5. The apparatus of claim 4 wherein the battery monitor transmits the indicator to the remote database.

6. The apparatus of claim 1 wherein the DC power bus upon which AC ripple is measured is electrically coupled between a rectifier and an inverter of the UPS system, such that a charge current may be provided on the bus from the rectifier or the plurality of batteries may provide power to the inverter during a power failure.

7. A method of processing power supply data comprising:
receiving a plurality of alternating current ripple measurements obtained from a power bus of an uninterruptible power supply system;
storing the AC ripple measurement in a database; and
providing for display of the AC ripple measurements by way of graphical user interface.

8. The method of claim 7 further comprising:
comparing the alternating current ripple measurements to one or more thresholds wherein the thresholds are each associated with one or more possible failure modes of the uninterruptible power supply system; and
generating an alert when the measurements meet one or more threshold values.

9. The method of claim 8 wherein the plurality alternating current ripple measurements are obtained from a direct current carrier signal on the power bus, and wherein the threshold value includes a threshold value associated with the direct current carrier signal.

10. The method of claim 7 wherein the plurality of alternating current ripple measurements are measured by one or more battery monitoring modules wherein each battery monitoring module is associated with a distinct battery cell of the uninterruptible power supply system.

11. The method of claim 7 wherein the one or more threshold values are associated with an increase in the alternating ripple current measurement as compared to a normal alternating current measurement, the increase representing at least 1.4 times the normal value.

12. The method of claim 7 wherein the plurality of alternating current values are peak-to-peak measurements.

13. The method of claim 1 further comprising:
detecting an increase in a direct current carrier signal upon which the AC ripple measurement is made.

14. The method of claim 13 further comprising:
generating an alert when an increase in the direct current carrier signal is detected.

15. The method of claim 13 further comprising:
generating an alert when an increase in the direct current carrier signal and an increase in AC ripple is measured.

16. The method of claim 7 further comprising:
detecting a decrease in the direct current carrier signal.

17. The method of claim 16 further comprising:
generating an alert when the decrease in the direct current carrier signal is detected.

18. The method of claim 7 further comprising:
generating an alert when a decrease in the measured AC ripple current or compared to a normal AC ripple current measurement.

19. The method of claim 7 wherein the alternating current ripple measurement is superimposed on a direct current carrier signal on the power bus.

20. The method of claim 7 wherein a plurality of failure modes associated with a change in the AC ripple measurement include malfunction of one or more capacitors in a rectifier of the UPS system, malfunction of silicon controlled rectifier components, malfunction of battery modules of the UPS system, malfunction of an inverter of the UPS system, the battery monitors, and connections in the UPS system.
